(19) United States
(12) Patent Application Publication
(10) Pub. No.: US 2020/0194650 A1
(43) Pub. Date: Jun. 18, 2020

(54) DUAL THERMOELECTRIC COMPONENT APPARATUS WITH THERMAL TRANSFER COMPONENT

(71) Applicant: Micron Technology, Inc., Boise, ID (US)

(72) Inventors: Daniel G. Scobee, Ione, CA (US); Aleksandr Semenuk, Organgevale, CA (US); Aswin Thiruvengadam, Folsom, CA (US)

(21) Appl. No.: 16/218,029

(22) Filed: Dec. 12, 2018

(51) Int. Cl. H01L 35/32; G01K 7/14; G01N 25/18; H05K 1/02

(52) U.S. Cl. CPC H01L 35/32; G01K 7/14; H05K 2201/10219; H05K 1/0203; G01N 25/18

(57) ABSTRACT

A first thermoelectric component (TEC) includes a top surface and a bottom surface. The first TEC is configured to concurrently increase temperature of the top surface and decrease temperature of the bottom surface or vice versa to transfer thermal energy between the top surface and the bottom surface based on a voltage potential applied to the first TEC. A thermal transfer component includes a top surface and a bottom surface. The bottom surface of the thermal transfer component is coupled to the top surface of the first TEC. The thermal transfer component is tapered such that the bottom surface is smaller than the top surface. A second TEC includes a top surface and a bottom surface. The bottom surface of the second TEC is coupled to the top surface of the thermal transfer component. The second TEC is larger than the first TEC.

### TECHNICAL FIELD

The present disclosure generally relates to a thermoelectric component, and more specifically, relates to a thermal transfer component disposed between thermoelectric components.

### BACKGROUND

A memory sub-system can be a storage system, such as a solid-state drive (SSD), or a hard disk drive (HDD). A memory sub-system can be a memory module, such as a dual in-line memory module (DIMM), a small outline DIMM (SO-DIMM), or a non-volatile dual in-line memory module (NVDIMM). A memory sub-system can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various implementations of the disclosure.

FIG. 1 illustrates an example environment to allocate test resources to perform a test of memory components, in accordance with some embodiments of the disclosure.

FIGS. 2A-2C illustrate a temperature control component, in accordance with some embodiments of the disclosure.

FIG. 3 illustrates a system to test an electrical device under a variety of thermal conditions, in accordance with embodiments of the disclosure.

FIG. 4 illustrates an example computing environment that includes a memory sub-system, in accordance with some embodiments of the disclosure.

FIG. 5 is a block diagram of an example computer system in which implementations of the present disclosure can operate.

### DETAILED DESCRIPTION

Aspects of the present disclosure are directed to a thermal transfer component that is disposed between a first thermoelectric component (TEC) and a second thermoelectric component. A memory sub-system is also hereinafter referred to as a “memory device.” An example of a memory sub-system is a storage device that is coupled to a central processing unit (CPU) via a peripheral interconnect (e.g., an input/output bus, a storage area network). Examples of storage devices include a solid-state drive (SSD), a flash drive, a universal serial bus (USB) flash drive, and a hard disk drive (HDD). Another example of a memory sub-system is a memory module that is coupled to the CPU via a memory bus. Examples of memory modules include a dual in-line memory module (DIMM), a small outline DIMM (SO-DIMM), a non-volatile dual in-line memory module (NVDIMM), etc. The memory sub-system can be a hybrid memory/storage sub-system. In general, a host system can utilize a memory sub-system that includes one or more memory components. The host system can provide data to be stored at the memory sub-system and can request data to be retrieved from the memory sub-system.

Electrical devices, such as memory components that are used in a memory sub-system, can be tested before being utilized in a system, such as the memory sub-system. In a conventional test process, the electrical devices can be placed into a chamber (i.e., an oven) that tests the electrical devices under various temperature conditions. For example, a single chamber can be used to test multiple memory components at a single time at a particular temperature. The test process can instruct various operations to be performed at the electrical devices at the particular temperature. Such operations can include, but are not limited to, read operations, write operations, or erase operations. The performance and behavior of the electrical devices can be observed or measured while the test process is performed. For example, performance characteristics (e.g., read or write latencies) and reliability of data stored at the memory components can be measured and recorded during the test process. However, since the chamber can only apply a single temperature to the electrical devices at any particular time, the testing of the electrical devices at many different temperatures can require a large amount of time as the test process will need to be performed for each desired temperature. Additionally, the chamber can only perform a single test process at a time. As such, performing different tests at the electrical devices at different operating conditions (e.g., different temperatures) can utilize a large amount of time if many different conditions of the test process for the electrical devices are desired.

A thermoelectric component (TEC) (also referred to as a “thermoelectric cooler”) can transduce electrical energy into thermal energy, and vice versa. A TEC can include two surfaces. When a voltage potential is applied to the TEC one surface heats while the other surface concurrently cools.

In some conventional systems, a thermoelectric component can be directly applied to an object, such as an electrical device, to change the temperature of the object. However, in some instances applying a single TEC to an electrical device does not transfer enough thermal energy to meet the temperature testing range (e.g., −40 degrees Celsius to 130 degrees Celsius) for some electrical devices.

A TEC can generate more thermal energy at one surface than the TEC dissipates at an opposing surface. For example, for every 1 degree Celsius change at a first surface of a TEC, the opposing surface of the TEC generates approximately 3 degrees Celsius. Since the TEC generates a disproportionate amount of heat for each degree of cooling, removing the excess heat from one surface while cooling an electrical device with an opposing surface can be challenging. The challenges are particularly acute when testing electrical devices at extremely low temperatures, as the amount of heat generated is a multiple of the heat removed. Using a single TEC is often not sufficient in transferring enough thermal energy to meet the temperature testing ranges for electrical devices

To address the removal of excess heat, two TECs with varying sizes can be stacked directly upon one another. For example, a larger TEC can be stacked directly above a smaller TEC. As the bottom surface of the smaller TEC cools an object, the top surface of the smaller TEC produces heat. The bottom surface of the larger TEC contacts the top surface of the smaller TEC and removes the heat generated by the top surface of the smaller TEC by cooling the bottom surface of the larger TEC. As the bottom surface of the larger TEC is cooled, the top surface of the larger TEC produces even more heat. The larger TEC can theoretically dissipate more thermal energy and help to dissipate the excess heat from the smaller TEC. However, stacking two TECs on top of one another can be highly inefficient and is often not sufficient in transferring enough thermal energy to meet the temperature testing ranges for electrical devices. When two TECs are stacked on one another, the heat generated by the smaller TEC is localized at the footprint of the smaller TEC and not evenly distributed over the entire bottom surface of the larger TEC. As such, the larger TEC does not efficiently remove heat from the top surface of the smaller TEC, which restricts the lower temperature that can be applied to the electrical device.

Aspects of the present disclosure address the above and other deficiencies by using a thermal transfer component that is disposed between two TECs. The thermal transfer component can be tapered so that a bottom surface that is coupled to a smaller TEC has a smaller surface area than a top surface that is coupled to larger TEC.

In an embodiment, two TECs can be different sizes where a bottom TEC is smaller than a top TEC. The thermal transfer component can include a bottom surface and a top surface. The bottom surface of the thermal transfer component is coupled to a top surface of the smaller TEC, and the top surface of the thermal transfer component is coupled to a bottom surface of the top TEC. The thermal transfer component can be tapered so that the bottom surface of the thermal transfer component is approximately the same size and shape as the top surface of smaller TEC, and the top surface of the thermal transfer component is approximately the same size and shape as the bottom surface of the larger TEC. As noted above, the larger TEC can have greater thermal energy transfer capabilities that a smaller TEC at least in part because of its larger surface area. To maximize the potential energy transfer capabilities of the larger TEC, the thermal energy generated by the top surface of the smaller TEC is transferred through the tapered thermal transfer component and spread across the entire bottom surface of the larger TEC (or at least a majority of the bottom surface). A tapered thermal transfer component allows for the efficient transfer of thermal energy between a smaller TEC and a larger TEC.

Advantages of the present disclosure include, but are not limited to, efficient thermal energy transfer between two differently sized TECs. With respect to testing electrical devices under a variety of thermal conditions, aspects of the present disclosure can concurrently apply a wide range of thermal conditions to electrical devices under test and concurrently apply different thermal conditions to electrical devices coupled to the same circuit board. Additionally, aspects of the present disclosure can apply thermal conditions in a temperature range that is broader and lower than conventional testing systems using TECs. As such, many different tests of the electrical devices can be performed more quickly and the reliability of the electrical devices can also be improved as any potential defects or flaws can be identified and later addressed in the design or manufacturing of the electrical devices.

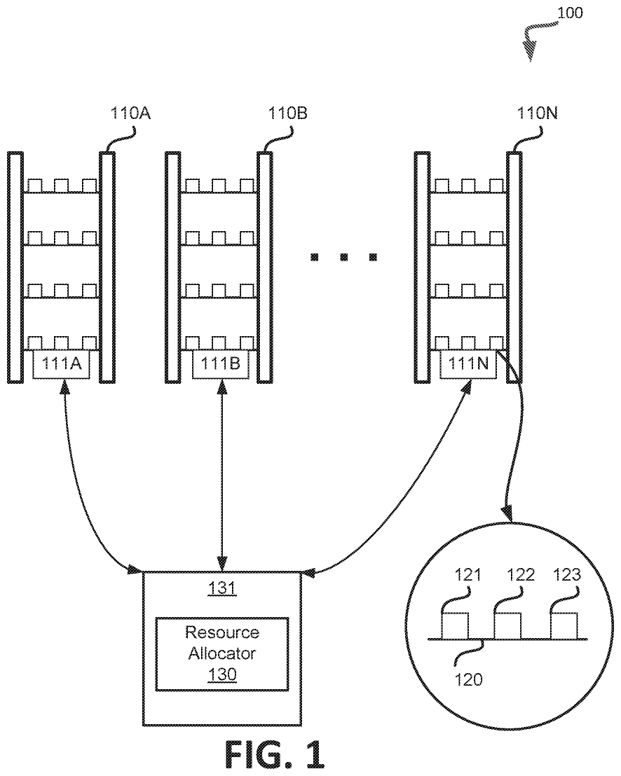

FIG. 1 illustrates an example environment to allocate test resources to perform a test of memory components, in accordance with some embodiments of the disclosure. A test platform 100 can include one or more racks 110A, 110B, and 110N. Each of the racks 110A, 110B, and 110N can include multiple test boards 120 where each test board 120 includes one or more test sockets (i.e., test resources). The test platform 100 can include any number of racks or test sockets. In some embodiments, a socket can refer to an electromechanical device that physically or electrically couples an electrical device, such as an active electrical device or passive electrical device, to a test board 120. A circuit board can be an example of a test board 120. In some embodiments, the electrical device can be a discrete component that is encased in a package (e.g., ceramic packaging material). The package material can have pins, solder bumps, or terminals external to the package that connect on-chip or on-die elements to off-chip or off-die elements (e.g., a power supply, other components at the circuit board, etc.).As shown, a test board 120 can include one or more test sockets. For example, a test board 120 can include a first test socket 121, a second test socket 122, and a third test socket 123. Although three test sockets are shown, a test board 120 can include any number of test sockets. In embodiments, each test socket can include an electrical device, such as a memory component, that has been embedded within the respective test socket. Additionally, each test socket can be fitted with a temperature control component that is used to apply a temperature condition to the embedded electrical device. For example, the temperature control component can be physical contact the package of a memory component to adjust the package temperature or on-die temperature to a desired temperature value in a temperature range. In some embodiments, the temperature range can be −40 degrees Celsius to 140 degrees Celsius.

In some embodiments, the temperature control component can be used to apply a temperature local to a respective electrical device that is different than a temperature that is applied by another temperature control component to another respective electrical device at the same or different test board 120. For example, a first temperature control component can apply a temperature of −20 degrees Celsius to a particular memory component, and another temperature control component located adjacent to the first temperature control component can apply a temperature of 100 degrees Celsius to another memory component that is located at the same test board 120.

In some embodiments, the temperature control component can be a dual thermoelectric component (TEC) (also referred to as “thermoelectric cooler” herein) (e.g., two TEC devices) that utilize a Peltier effect to apply a heating or cooling effect at a surface of the dual TEC device that is coupled to the embedded memory component. For example, a bottom part of the temperature control component can contact the package of the electrical device to transfer thermal energy to and from the electrical device. In some embodiments, the thermoelectric component can be a Peltier device. In some embodiments, the thermoelectric component can include an array of alternating n-type and p-type semiconductors disposed between two plates, such as two ceramic plates. A voltage applied to the thermoelectric component causes one plate to cool while another plate heats. In the same or alternative embodiments, the temperature control component can be placed on top of the memory component in the respective test socket.

As shown, each test rack 110A, 110B, and 110N can include multiple test boards 120. Each of the test boards 120 of a particular test rack can be coupled with a local test component. For example, each test rack 110A, 110B, and 110N can respectively include a local test component 111A, 111B, and 111N. Each of the local test components 111A, 111B, and 111N can receive instructions to perform a test or a portion of a test that is to be performed at the test sockets of the respective test rack. For example, a resource allocator component 130 can receive (e.g., from a user) conditions of the test that is to be performed and the resource allocator component 130 can determine particular test sockets across the different test boards 120 at one or more of the test racks 110A, 110B, and 110N that can be used by the test. In some embodiments, the resource allocator component 130 can be provided by a server 131. In some embodiments, the server 131 is a computing device or system that is coupled with the local test components 111A, 111B, and 111N over a network.

The temperate control component of each test socket 121, 122, and 123 of each test board 120 can be used to apply a different temperature condition to the respective embedded memory component. Furthermore, each test socket 121, 122, and 123 can be used to perform different operations at the embedded memory component.

The resource allocator component 130 can receive a test input from a user. The test input can specify conditions of the test that is to be performed with one or more memory components. For example, the test can specify particular temperature conditions that are to be applied to memory components and a sequence of operations that are to be performed at memory components under particular temperature conditions. The resource allocator 130 can retrieve a data structure that identifies available test sockets across the test platform 100 as well as characteristics of the available test sockets. Subsequently, the resource allocator component 130 can assign test sockets at the test platform 100 that include embedded memory components that match or satisfy the conditions of the test. The resource allocator component 130 can then transmit instructions to local test components of test racks that include test sockets that are to be used in the test.

In some embodiments, one or more of the test boards 120 of test platform 100 can be used with one or more thermal chambers (also referred to as a “micro-thermal chamber” or “enclosure” herein). For example, a test board 120 can include multiple test sockets 121, 122, and 123. A thermal chamber can be fitted above the multiple test sockets 121, 122, and 123. In another example, a different thermal chamber can be fitted above each of the multiple test sockets 121, 122, and 123. The thermal chamber can include one or more ports. The one or more ports can expose a cavity within the thermal chamber. The electrical devices coupled to the test sockets of test board 120 are accessible from the one or more ports. In some embodiments, the one or more ports are configured to receive a temperature control component. In some embodiments, the bottom part of the temperature control component extends within the cavity of the thermal chamber and contacts a respective electrical device. The top part of the temperature control component, such a heat sink, can extend above the thermal chamber. In some embodiments, the temperature control component can be coupled to the thermal chamber. In some embodiments, the thermal chamber can be used to hold the temperature control component in-place. In some embodiments, the thermal chamber can align the temperature control component with the respective test socket and respective electrical device so that the bottom part of the temperature control component can make physical contact the respective electrical device. In embodiments where the thermal chamber includes multiple ports that hold multiple temperature control components, the thermal chamber can used to help apply the temperature control component with similar or equal or consistent pressure to each of the respective electrical devices. The multiple temperature control components can concurrently apply different temperatures to the respective electrical device within the thermal chamber.

In some embodiments the thermal chamber can include a gas port to receive a gas, such as oil free air (OFA) or nitrogen gas or clean dry air or gas (CDA). In some embodiments, the gas can have a dew point lower than the expected cold temperatures range under test. In some embodiments, the gas can have less than 1 part-per-million (ppm) carbon dioxide and less than 0.003 ppm hydrocarbon vapor. The gas provided to the chamber can have a dew point that is lower than the testing conditions so that condensate, such as moisture or ice, does not form at the electrical devices during test. For example, the package of the electrical device under test can be controlled within a temperature range from −25 degrees Celsius to 140 degrees Celsius. The dew point of the gas can be below −25 degrees Celsius (e.g., −60 degrees Celsius). In some embodiments, rather than sealing the thermal chamber, the thermal chamber (e.g., cavity within the chamber) can be maintained as a positive pressure environment so that the only gas going into the chamber is from the gas port, and the only gas escaping the chamber is gas from the gas port.

In embodiments, rather than changing the temperature of the thermal chamber using hot or cold gas, the temperature control component can maintain the temperature environment local to each electrical device under test. In embodiments where the thermal chamber includes multiple temperature control components coupled to multiple electrical devices, each of the temperature control components can maintain a different (or same) temperature environment local to the respective electrical devices under test without using hot or cold gas. For example, a first electrical device under test can contact a first temperature control component. A second electrical device under test can contact a second control component. Both the first and the second temperature control component can be coupled to a single thermal chamber. The first temperature control component can maintain a temperature of the first electrical device at 100 degrees Celsius while the second temperature control component can maintain a temperature of the second electrical device at 0 degrees Celsius.

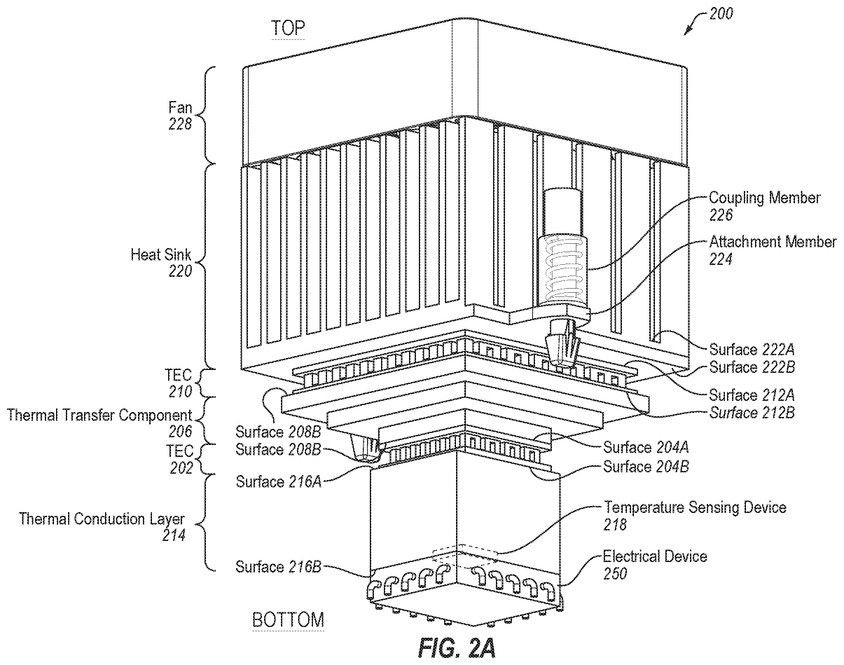

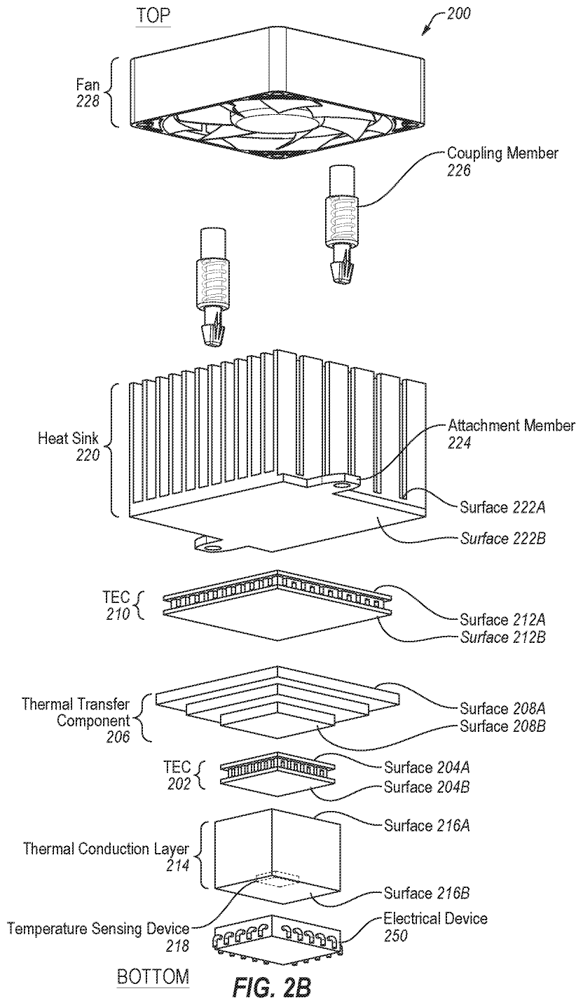

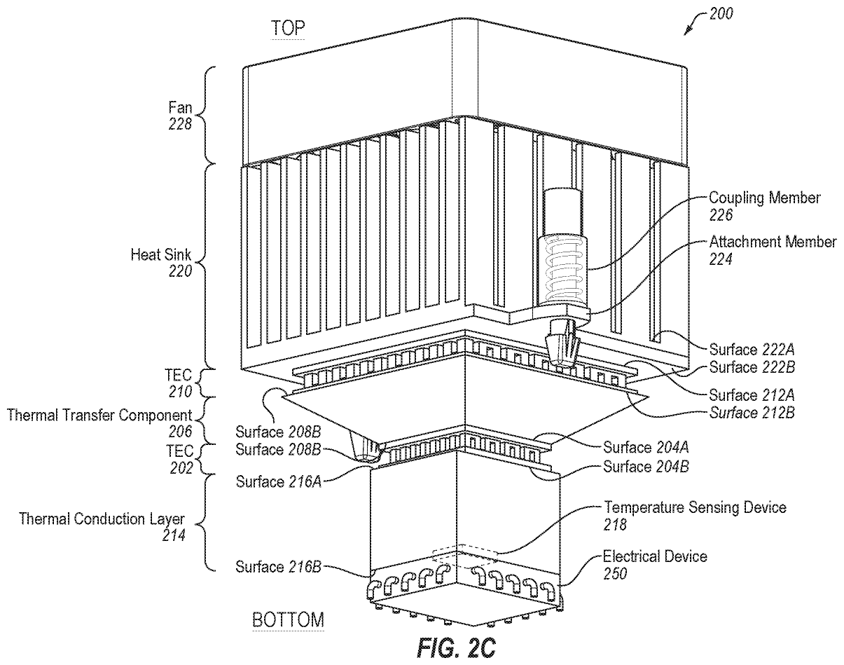

FIGS. 2A-2C illustrate a temperature control component, in accordance with some embodiments of the disclosure. FIG. 2A illustrates a collapsed view of temperature control component 200, in accordance with some embodiments of the disclosure. FIG. 2B illustrates an expanded view of temperature control component 200, in accordance with some embodiments of the disclosure. FIG. 2C illustrates temperature control component with a thermal transfer component 206 in an alternative shape, in accordance with some embodiments of the disclosure. Temperature control component 200 is illustrated with a number of elements for purposes of illustration, rather than limitation. In other embodiments, temperature control component 200 can include the same, different, fewer, or additional elements. Temperature control component 200 is illustrated with relative positional relationships, top and bottom, for purposes of illustration rather than limitation. It can be noted that assigning other positional relationships to temperature control component 200 and the elements of the temperature control component 200 is within the scope of the disclosure.

In embodiments, temperature control component 200 includes thermoelectric component (TEC) 202. In embodiments, the TEC, such as TEC 202, can serve as a heat pump to deliver heat to or remove heat from a surface. TEC 202 includes two surfaces 204, top surface 204A and bottom surface 204B. A TEC, such as TEC 202, is configured to concurrently increase the temperature of the top surface (e.g., top surface 204A) and decrease temperature of the bottom surface (e.g., bottom surface 204B), or concurrently decrease the temperature of the top surface (e.g., top surface 204A) and increase the temperature of the bottom surface (e.g., bottom surface 204B) based on a voltage potential applied to the TEC. In embodiments, the TEC, such as TEC 202 and TEC 210, includes a set of electrical wires to couple a voltage potential to the TEC and deliver the requisite current to the TEC.

In embodiments, temperature control component 200 includes TEC 210. TEC 210 can include two surfaces 212, such as top surface 212A and bottom surface 212B. In embodiments, the bottom surface 212B is coupled to the top surface 208A of thermal transfer component 206. In embodiments, TEC 210 is larger than TEC 202. In some embodiments, the bottom surface 212B of TEC 210 has a surface area approximately two times larger than the surface area of the top surface 204A of TEC 202. In some embodiments, TEC 210 is sized to efficiently transfer heat away from TEC 202. In some embodiments, TEC 210 has a minimum of two times the heat transfer capability of the TEC 202. As noted herein, the TEC 210 can have a surface area that is two times the surface area of TEC 202 so that the heat transfer capability of TEC 210 is at least two times that of TEC 202. It can be noted that in some embodiments, that TEC 210 can have a surface area that is similar to TEC 202 (or at least less than twice the surface area of TEC 202) but have twice the power and heat transfer capability.

For purposes of illustration rather than limitation, square TECs are illustrated. In other embodiments, TECs of different shapes can be implemented, such a rectangular TECs or round TECs. In some embodiments, the two TECs can be different shapes. The selected TECs can be based on the surface shape of the electrical device 250. For example, if the package of electrical device 250 is square using a square TEC (at least for TEC 202) can help to optimally transfer thermal energy to and from electrical device 250. It can be noted that using TECs with different shapes is within the scope of the disclosure.

In embodiments, temperature control component 200 includes thermal transfer component 206. In embodiments, the thermal transfer component 206 efficiently conducts thermal energy from a surface of one TEC to an opposing surface of another TEC. For example, to cool electrical device 250 under test, bottom surface 204B of TEC 202 removes thermal energy (e.g., heat) from the top surface of electrical device 250. The top surface 204A of TEC 202 concurrently generates thermal energy, which is transferred via thermal transfer component 206 to the bottom surface 212B of TEC 210.

In embodiments, the thermal transfer component 206 is composed or made of a thermally conductive material. Thermally conductive materials include, but is not limited to, copper, aluminum, copper brass, or alloys of the aforementioned materials. It can be noted that other thermally conductive materials can be used. It can also be noted that materials having a higher thermal conductivity (k) can more efficiently transfer thermal energy between TEC 202 and TEC 210.

In embodiments, thermal transfer component 206 includes at least two surfaces 208, including a top surface 208A and a bottom surface 208B. The bottom surface 208B of thermal transfer component 206 is coupled to the top surface 204A of TEC 202. The top surface 208A of thermal transfer component 206 is coupled to the bottom surface 212B of TEC 210.

In some embodiments, the thermal transfer component 206 can be coupled to a surface of an adjacent element using a thermal interface material, such as thermally conductive adhesive, thermal greases, phase change materials, thermal tapes, gap filling thermal pads, thermal epoxies, and so forth. For example, a thermal interface material can be disposed between the top surface 204A of TEC 202 and the bottom surface 208B of thermal transfer component 206, and between the top surface 208A of thermal transfer component 206 and the bottom surface 212B of TEC 210. In some embodiments, the thermal interface material can have at least a minimum conductivity of 150 Watts per meter-Kelvin (W/mk) or greater.

In embodiments, the thermal transfer component 206 is tapered such the bottom surface 208B is smaller than the top surface 208A. In some embodiments, the top surface 208A of the thermal transfer component 206 has a surface area that is approximately two times larger than a surface area of the bottom surface 208B of the thermal transfer component 206. In some embodiments, the thermal transfer component 206 can be tapered based on the dimensions of the TECs 202 and 210. For example, the thermal transfer component 206 can be tapered such that the bottom surface 208B is at a size that is based on a size of the top surface 204A of the TEC 202 and the top surface 208A can be at a size that is based on a size of the bottom surface 212B of the TEC 210. In some embodiments, top surface 208A and bottom surface 208B of thermal transfer component 206 are sized to match or be close in size to the surface of the respective TEC. In some embodiments, one or more of top surface 208A and bottom surface 208B of thermal transfer component 206 can have a surface area that is 95% to 120% the surface area of the respective surface of the respective TEC.

In embodiments, a surface of a TEC generates more thermal energy than an opposing surface of the TEC dissipates. For example, for every 1 degree Celsius change at bottom surface 204B of TEC 202, the top surface 204A of TEC 202 generates approximately 3 degrees Celsius. A larger TEC 210 can have greater thermal energy transfer capabilities at least in part because of its larger surface area. To maximize the potential energy transfer capabilities of the larger TEC, the thermal energy can be spread across the entire surface of the larger TEC. A tapered thermal transfer component 206 allows for the efficient transfer of thermal energy between a smaller TEC 202 and a larger TEC 210. For example, heat from top surface 204A of TEC 202 is conducted through thermal transfer component 206 and spread across the bottom surface 212B of TEC 210 using a tapered thermal transfer component 206. The larger TEC 210 can move the thermal energy from the bottom surface 212B to the opposing surface (e.g., top surface 212A).

In embodiments, the thermal transfer component 206 can be step pyramid shaped as illustrated in FIG. 2A and 2B. In other embodiments, thermal transfer component 206 can have different shapes, such as a flat-sided pyramid that is tapered from a top surface to a bottom surface as illustrated in FIG. 2C. In some embodiments, the shape of the thermal transfer component 206 can be based in part on the shape of the TEC that contacts a surface of the thermal transfer component 206. For example, in implementations that use round TECs the shape of the thermal transfer component 206 can be conical where the bottom surface and the top surface of the thermal transfer component 206 are round. In some embodiments, the thickness of the thermal transfer component 206 (between surface 208A and surface 208B) is greater than or equal to the thickness of one of TEC 202 or TEC 210.

In some embodiments, the thermal transfer component 206 can include a thermal conduction layer 214. The thermal conduction layer 214 layer can include a top surface 216A and a bottom surface 216B. In embodiments, the top surface 216A of the thermal conduction layer 214 is coupled to the bottom surface 204B of TEC 202. In some embodiments, the thermal conduction layer 214 can transfer thermal energy from the bottom surface 204B of TEC 202 to the bottom surface 216B of thermal conduction layer 214.

In some embodiments, the bottom surface 216B of thermal conduction layer 214 can be positioned to contact the top surface of electrical device 250. For example, the bottom surface 216B of thermal conduction layer 214 can be positioned to contact the top surface of the package of the electrical device 250 so that the package temperature of the electrical device 250 or the on-chip temperature of the electrical device 250 can be controlled to a desired temperature. In some embodiments, the thermal conduction layer 214 can be configured to fit within the socket that couples the electrical device 250 to a circuit board so that the bottom surface 216B of the thermal conduction layer 214 can physically contact the package of the electrical device 250 and transfer thermal energy.

In embodiments, the thermal conduction layer 214 can be coupled to TEC 202 using a thermal interface material, as described above. In embodiments, the thermal conduction layer 214 is composed of or made from a thermally conductive material, as described above.

In embodiments, the top surface 216A of thermal conduction layer 214 can be approximately that same size and the same shape as the bottom surface 204B of TEC 202. In some embodiments, the size and shape of surfaces 216 of thermal conduction layer 214 can be based on the size and shape of the top surface (e.g., contact surface) of the electrical device 250. For example, the thermal conduction layer 214 can be shaped so that the bottom surface 216B contacts most if not all (in some cases, more than) the top surface of electrical device 250. In some embodiments, the top surface 216A of the thermal conduction layer 214 is approximately the same size or larger than the bottom surface 204B of TEC 202. In some embodiments, the bottom surface 216B of the thermal conduction layer 214 can be the same size and shape as the top surface 216A of the thermal conduction layer 214. For example, the thermal conduction layer 214 can be a square cube or a rectangular cube. In some embodiments, the thermal conduction layer 214 can be tapered in one direction or another, e.g., from top surface 216A to bottom surface 216B or vice versa. It can be noted that that shape of thermal conduction layer 214 can be based at least in part on the shape of TEC 202 or the electrical device 250.

In some embodiments, thermal conduction layer 214 can be an optional element and TEC 202 can make direct physical contact with electrical device 250 to transfer thermal energy to and from electrical device 250.

In some embodiments, the temperature control component 200 can include a thermal sensing device 218. In some embodiments, the thermal sensing device 218 can be disposed or embedded within the thermal conduction layer 214. The thermal sensing device 218 can be located within thermal conduction layer 214 so that the temperature sensing surface of the thermal sensing device 218 is in close proximity to the bottom surface 216B of thermal conduction layer 214. Thermal sensing device 218 can be used to measure the temperature applied to the package of electrical device 250, which can effectively represent the temperature at the package of the electrical device 250 due to the low thermal resistance (k) of thermal conduction layer 214. In embodiments, the thermal sensing device 218 can be any temperature sensing device such as a thermocouple, capacitive temperature sensing device, resistive temperature sensing device, and so forth. In embodiments, the thermal sensing device 218 can include a set of electrical wires to couple the thermal sensing device 218 to a measurement unit to measure the output of the thermal sensing device 218.

In some embodiments, the electrical device 250 can include one or more temperature sensing devices, such as an on-chip temperature sensing device. The on-chip temperature can be different than the package temperature of the electrical device 250 due to thermal resistance of the package. Temperature measurements from the on-chip temperature sensing device, the thermal sensing device 218 of the thermal conduction layer 214, or both can be used to perform thermal testing at the electrical device 250. For example, the temperature measurements can be used to determine a particular voltage potential to apply to the temperature control component 200 or a change to the particular voltage potential to apply to the temperature control component 200 during the thermal testing of the electrical device 250.

In some embodiments, temperature control component 200 can include a heat sink 220. The heat sink 220 can include a top surface 222A and a bottom surface 222B. In embodiments, the top surface 222A can include a greater surface area than the bottom surface 222B to help facilitate thermal energy transfer from the heat sink 220 to an adjacent medium. In embodiments, the bottom surface 222B of heat sink 220 is coupled to the top surface 212A of TEC 210 to transfer thermal energy from TEC 210 to the heat sink 220. In embodiments, the heat sink 220 and TEC 210 are coupled using a thermal interface material, as described above. In embodiments, the heat sink 220 is composed of thermally conductive material, as described above.

In some embodiments, the heat sink 220 is a passive mechanical device. In embodiments, the top surface 222A of the heat sink 220 includes multiple channels and multiple fins disposed between the channels. In other embodiments, the heat sink 220 can be another type of heat sink, such a liquid cooled heat sink and so forth.

In some embodiments, heat sink 220 includes one or more attachment members 224. In embodiments, the attachment members can be used to secure the temperature control component 200 to a thermal chamber. In some embodiments, the attachment members 224 are configured to receive adjustable coupling members 226 that can adjustably couple the temperature control component 200 to a thermal chamber. In some embodiments, the adjustable coupling member can include a spring element that allows a vertical position of the temperature control component 200 that is mounted to the thermal chamber to be adjusted.

In some embodiments, temperature control component 200 can include a fan, such as electric fan 228. In embodiments, the electric fan 228 is disposed above the top surface 222A of heat sink 220 and used to transfer thermal energy from the heat sink 220 to an adjacent medium, such as the gas medium local the temperature control component 200. The electrical fan 228 can include a set of electric wires that are coupled to a voltage potential.

A single thermal transfer component 206 is shown for purposes of illustration, rather than limitation. In other embodiments, multiple thermal transfer components 206 can be used. For example, an additional thermal transfer component can be stacked on the top surface 212A of TEC 210. The additional thermal transfer component can be larger than thermal transfer component 206. For example, the bottom surface of the additional thermal transfer component can be approximately the same size as the top surface 212A of TEC 210. The additional thermal transfer component can be tapered such that the top surface of the additional thermal transfer component is larger than the bottom surface. In embodiments, the top surface of the additional thermal transfer component can be coupled to a TEC that is larger than (e.g., greater surface area) TEC 210. Any number of additional thermal transfer components or TECs can be implemented in other embodiments.

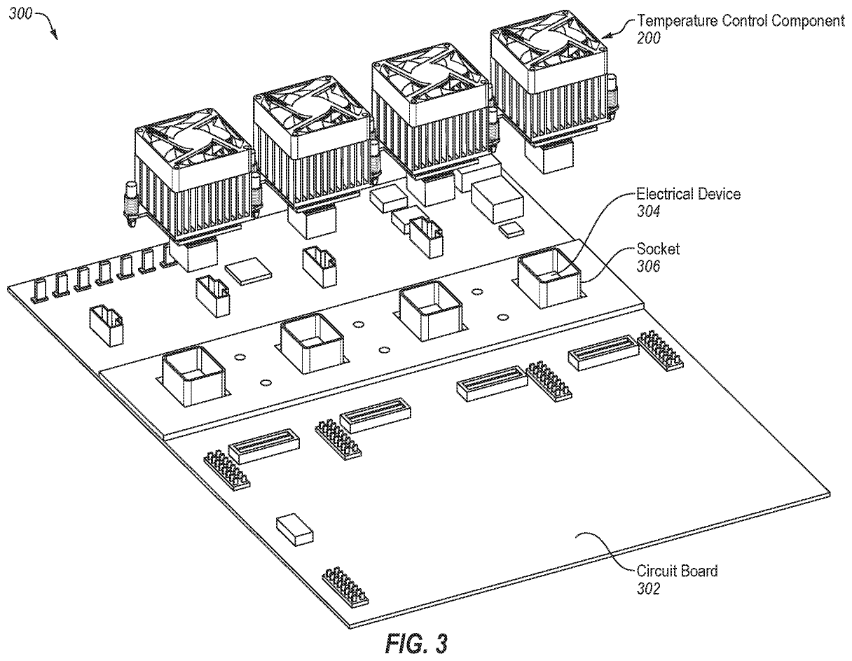

FIG. 3 illustrates a system to test an electrical device under a variety of thermal conditions, in accordance with embodiments of the disclosure. It can be noted that a temperature control component, such as temperature control component 200 of FIG. 2, can be used with or be part of system 300. Elements of temperature control component 200 of FIG. 2 are used to help illustrate aspects of FIG. 3. System 300 can be used to test one or more electrical devices 304 under a variety of thermal conditions as described herein.

In some embodiments, a temperature control component 200 can be placed above an electrical device 304 under test. As described above, a test process can be performed at the electrical device 304 to instruct various operations to be performed at the electrical device maintained at one more predetermined temperatures using temperature control component 200. The temperatures under which the electrical device 304 is tested can be controlled by the temperature control component 200. The bottom part of the temperature control component 200, such as the bottom surface 216B of the thermal conduction layer 214, can physically contact a top surface of the electrical device 304. The temperature control component 200 can transfer thermal energy to and from the electrical device 304. For example, temperature control component 200 can change the temperature of the electrical device 304 (e.g., package temperature or on-die temperature) in a temperature range from −40 degrees Celsius to 140 degrees Celsius.

System 300 can include a circuit board 302. The circuit board 302 can be coupled to one or more electrical devices 304 under test. In embodiments, the circuit board 302 can facilitate electrical signal transfer to and from the one or more electrical devices 304 and to and from any additional elements coupled to the circuit board 302. In embodiments, the circuit board 302 can facilitate power transmission to and from the one or more electrical devices 304 and to and from any additional elements coupled to the circuit board 302. In some embodiments, the circuit board 302 can be used to transmit instructions to perform read operations, write operations, or erase operations at the one or more electrical devices 304 during the performance of the thermal test. Furthermore, the circuit board 302 can be used to retrieve information or test data from the electrical devices 304 during the performance of the thermal test.

In some embodiments, the system 300 can include one or more sockets 306. Socket 306 can be an electromechanical device that couples an electrical device 304 to the circuit board 302. In embodiments, the sides of the socket 306 can extend vertically beyond the top surface of the electrical device 304. The bottom part of the temperature control component 200 (e.g., at least part of the thermal conduction layer 214) can be fitted within the socket 306.

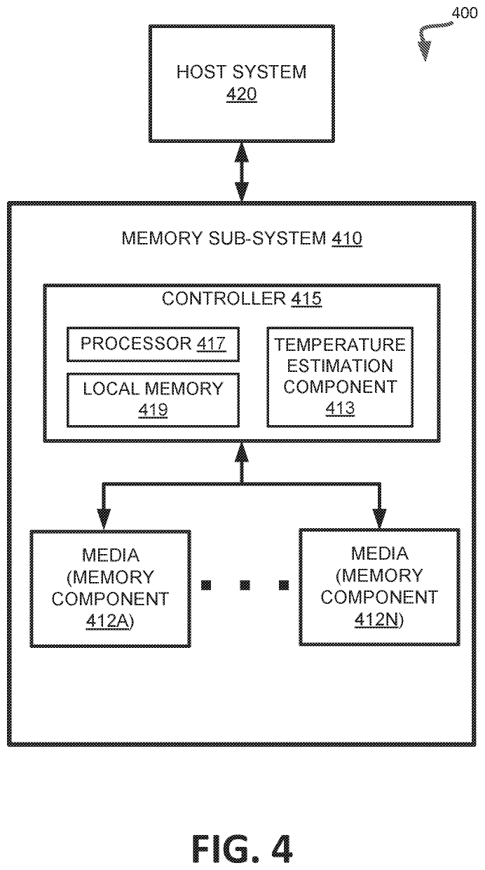

FIG. 4 illustrates an example computing environment 400 that includes a memory sub-system 410 in accordance with some embodiments of the disclosure. The memory sub-system 410 can include media, such as memory components 412A to 412N. The memory components 412A to 412N can be volatile memory components, non-volatile memory components, or a combination of such. In some embodiments, the memory sub-system is a storage system. An example of a storage system is a SSD. In some embodiments, the memory sub-system 410 is a hybrid memory/storage sub-system. In general, the computing environment 400 can include a host system 420 that uses the memory sub-system 410. For example, the host system 420 can write data to the memory sub-system 410 and read data from the memory sub-system 410.

The host system 420 can be a computing device such as a desktop computer, laptop computer, network server, mobile device, or such computing device that includes a memory and a processing device. The host system 420 can include or be coupled to the memory sub-system 410 so that the host system 420 can read data from or write data to the memory sub-system 410. The host system 420 can be coupled to the memory sub-system 410 via a physical host interface. As used herein, “coupled to” generally refers to a connection between components, which can be an indirect communicative connection or direct communicative connection (e.g., without intervening components), whether wired or wireless, including connections such as electrical, optical, magnetic, etc. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), etc. The physical host interface can be used to transmit data between the host system 420 and the memory sub-system 410. The host system 420 can further utilize an NVM Express (NVMe) interface to access the memory components 412A to 412N when the memory sub-system 410 is coupled with the host system 420 by the PCIe interface. The physical host interface can provide an interface for passing control, address, data, and other signals between the memory sub-system 410 and the host system 420.

The memory components 412A to 412N can include any combination of the different types of non-volatile memory components and/or volatile memory components. An example of non-volatile memory components includes a negative-and (NAND) type flash memory. Each of the memory components 412A to 412N can include one or more arrays of memory cells such as single level cells (SLCs) or multi-level cells (MLCs) (e.g., triple level cells (TLCs) or quad-level cells (QLCs)). In some embodiments, a particular memory component can include both an SLC portion and a MLC portion of memory cells. Each of the memory cells can store one or more bits of data (e.g., data blocks) used by the host system 420. Although non-volatile memory components such as NAND type flash memory are described, the memory components 412A to 412N can be based on any other type of memory such as a volatile memory. In some embodiments, the memory components 412A to 412N can be, but are not limited to, random access memory (RAM), read-only memory (ROM), dynamic random access memory (DRAM), synchronous dynamic random access memory (SDRAM), phase change memory (PCM), magneto random access memory (MRAM), negative-or (NOR) flash memory, electrically erasable programmable read-only memory (EEPROM), and a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. Furthermore, the memory cells of the memory components 412A to 412N can be grouped as a group of memory cells, wordlines, wordline groups (e.g., multiple wordlines in a group), or data blocks that can refer to a unit of the memory component used to store data.

The memory system controller 415 (hereinafter referred to as “controller”) can communicate with the memory components 412A to 412N to perform operations such as reading data, writing data, or erasing data at the memory components 412A to 412N and other such operations. The controller 415 can include hardware such as one or more integrated circuits and/or discrete components, a buffer memory, or a combination thereof. The controller 415 can be a microcontroller, special purpose logic circuitry (e.g., a field programmable gate array (FPGA), an application specific integrated circuit (ASIC), etc.), or other suitable processor. The controller 415 can include a processor (e.g., processing device) 417 configured to execute instructions stored in local memory 419. In the illustrated example, the local memory 419 of the controller 415 includes an embedded memory configured to store instructions for performing various processes, operations, logic flows, and routines that control operation of the memory sub-system 410, including handling communications between the memory sub-system 410 and the host system 420. In some embodiments, the local memory 419 can include memory registers storing memory pointers, fetched data, etc. The local memory 419 can also include read-only memory (ROM) for storing micro-code. While the example memory sub-system 410 in FIG. 4 has been illustrated as including the controller 415, in another embodiment of the disclosure, a memory sub-system 410 cannot include a controller 415, and can instead rely upon external control (e.g., provided by an external host, or by a processor or controller separate from the memory sub-system).

In general, the controller 415 can receive commands or operations from the host system 420 and can convert the commands or operations into instructions or appropriate commands to achieve the desired access to the memory components 412A to 412N. The controller 415 can be responsible for other operations such as wear leveling operations, garbage collection operations, error detection and error-correcting code (ECC) operations, encryption operations, caching operations, and address translations between a logical block address and a physical block address that are associated with the memory components 412A to 412N. The controller 415 can further include host interface circuitry to communicate with the host system 420 via the physical host interface. The host interface circuitry can convert the commands received from the host system into command instructions to access the memory components 412A to 412N as well as convert responses associated with the memory components 412A to 412N into information for the host system 420.

The memory sub-system 410 can also include additional circuitry or components that are not illustrated. In some embodiments, the memory sub-system 410 can include a cache or buffer (e.g., DRAM) and address circuitry (e.g., a row decoder and a column decoder) that can receive an address from the controller 415 and decode the address to access the memory components 412A to 412N.

The memory sub-system 410 includes a temperature estimation component 413 that performs operations as described herein. In some embodiments, the temperature estimation component 413 can be part of host system 420, controller 415, memory component 412N, an operating system, or an application. Temperature estimation component 413 can generate an estimated temperature for the memory sub-system 410. For example, the controller 415 can include a processor 417 (processing device) configured to execute instructions stored in local memory 419 for performing the operations described herein.

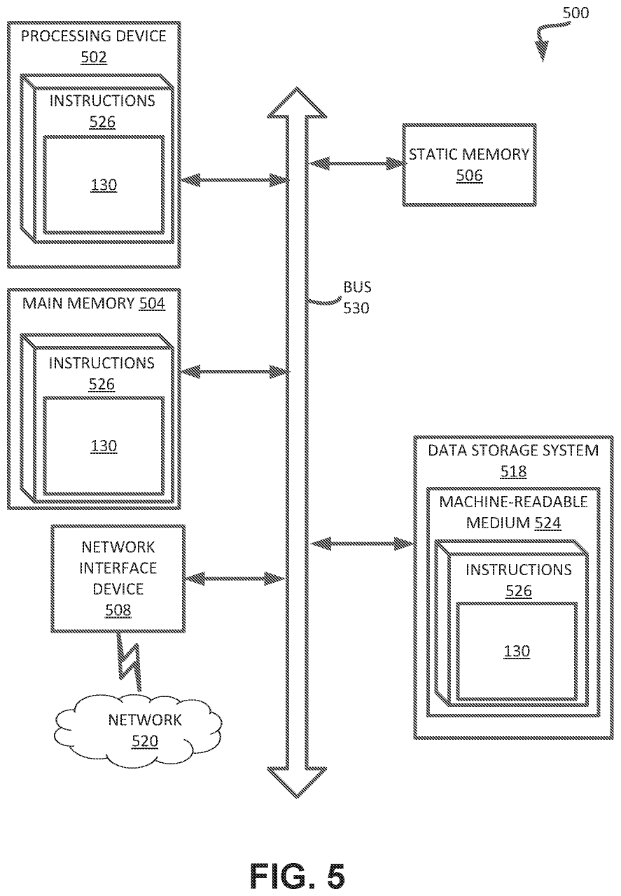

FIG. 5 illustrates an example machine of a computer system 500 within which a set of instructions, for causing the machine to perform any one or more of the methodologies discussed herein, can be executed. In some embodiments, the computer system 500 can correspond to a host or server system that includes, is coupled to, or utilizes a test platform (e.g., to execute operations corresponding to the resource allocator component 130 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to a memory sub-system.

In one embodiment, the instructions 526 include instructions to implement functionality corresponding to a resource allocator component (e.g., the resource allocator component 130 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims may generally be construed to mean “one or more” unless specified otherwise or clear from context to be directed to a singular form. Moreover, use of the term “an implementation” or “one implementation” or “an embodiment” or “one embodiment” or the like throughout is not intended to mean the same implementation or implementation unless described as such. One or more implementations or embodiments described herein may be combined in a particular implementation or embodiment. The terms “first,” “second,” “third,” “fourth,” etc. as used herein are meant as labels to distinguish among different elements and may not necessarily have an ordinal meaning according to their numerical designation.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus comprising:
a first thermoelectric component (TEC) comprising a top surface and a bottom surface, the first TEC configured to concurrently increase temperature of the top surface and decrease temperature of the bottom surface or to concurrently decrease the temperature of the top surface and increase the temperature of the bottom surface to transfer thermal energy between the top surface and the bottom surface based on a voltage potential applied to the first TEC;
a thermal transfer component comprising a top surface and a bottom surface, wherein the bottom surface of the thermal transfer component is coupled to the top surface of the first TEC, and wherein the thermal transfer component is tapered such that the bottom surface is smaller than the top surface; and
a second TEC comprising a top surface and a bottom surface, wherein the bottom surface of the second TEC is coupled to the top surface of the thermal transfer component, and wherein the second TEC is larger than the first TEC.

2. The apparatus of claim 1, wherein the top surface of the thermal transfer component has a surface area approximately two times larger than a surface area of the bottom surface of the thermal transfer component.

3. The apparatus of claim 1, further comprising:
a thermal conduction layer comprising a top surface and a bottom surface, wherein the top surface of the thermal conduction layer is coupled to the bottom surface of the first TEC.

4. The apparatus of claim 3, further comprising:
a temperature sensing device disposed within the thermal conduction layer.

5. The apparatus of claim 3, wherein the top surface of the thermal conduction layer is approximately a same size or a larger size than the bottom surface of the first TEC, wherein the bottom surface of the thermal conduction layer to couple with a package of an electrical device.

6. The apparatus of claim 1, further comprising:
a heat sink comprising a top surface and a bottom surface, wherein the bottom surface of the heat sink is coupled to the top surface of the second TEC to transfer the thermal energy from the second TEC to the heat sink.

7. The apparatus of claim 6, wherein the heat sink is a passive mechanical device, wherein the top surface of the heat sink comprises a plurality of channels and a plurality of fins disposed between the plurality of channels.

8. The apparatus of claim 6, further comprising:
an electric fan disposed above the top surface of the heat sink to transfer the thermal energy from the heat sink to an adjacent medium.

9. The apparatus of claim 6, further comprising:
a plurality of attachment members of the heat sink, the plurality of attachment members to receive a plurality of adjustable coupling members to adjustably couple the apparatus to a thermal chamber.

10. The apparatus of claim 1, further comprising:
a thermal interface material disposed between the top surface of the first TEC and the bottom surface of the thermal transfer component, and between the top surface of the thermal transfer component and bottom surface of the second TEC.

11. The apparatus of claim 1, wherein the bottom surface of the second TEC has a surface area approximately two times larger than a surface area of the top surface of the first TEC.

12. The apparatus of claim 1, wherein the apparatus is to couple to a package of an electrical device and is configured to adjust the temperature applied to the package of the electrical device in a temperature range.

13. A system to test an electrical device under a variety of thermal conditions, the system comprising:
a circuit board;
the electrical device coupled to the circuit board; and
a temperature control component to contact the electrical device to transfer thermal energy to and from the electrical device, the temperature control component comprising:
a first thermoelectric component (TEC) comprising a top surface and a bottom surface, the first TEC configured to concurrently increase temperature of the top surface and decrease temperature of the bottom surface or to concurrently decrease the temperature of the top surface and increase the temperature of the bottom surface to transfer the thermal energy between the top surface and the bottom surface based on a voltage potential applied to the first TEC;
a thermal transfer component comprising a top surface and a bottom surface, wherein the bottom surface of the thermal transfer component is coupled to the bottom surface of the first TEC, and wherein the thermal transfer component is tapered such that the bottom surface is smaller than the top surface; and
a second TEC comprising a top surface and a bottom surface, wherein the bottom surface of the second TEC is coupled to the top surface of the thermal transfer component, and wherein the second TEC is larger than the first TEC.

14. The system of claim 13, wherein the top surface of the thermal transfer component has a surface area approximately two times larger than a surface area of the bottom surface of the thermal transfer component.

15. The system of claim 13, the temperature control component further comprising:
a thermal conduction layer comprising a top surface and a bottom surface, wherein the top surface of the thermal conduction layer is coupled to the bottom surface of the first TEC.

16. The system of claim 15, the temperature control component further comprising:
a temperature sensing device disposed within the thermal conduction layer.

17. The system of claim 15, wherein the top surface of the thermal conduction layer is approximately a same size or a larger size than the bottom surface of the first TEC, wherein the bottom surface of the thermal conduction layer to couple with a package of the electrical device.

18. The system of claim 13, the temperature control component further comprising:
a heat sink comprising a top surface and a bottom surface, wherein the bottom surface of the heat sink is coupled to the top surface of the second TEC to transfer the thermal energy from the second TEC to the heat sink.

19. The system of claim 13, further comprising:
a socket that couples the electrical device to the circuit board, wherein a bottom surface of the temperature control component to fit within the socket and physically contact a package of the electrical device to transfer the thermal energy.

20. A system comprising:
a first thermoelectric component (TEC) to vary a temperature between a top surface of the first TEC and a bottom surface of the first TEC based on a voltage potential applied to the first TEC;
a thermal transfer component comprising a top surface and a bottom surface, wherein the bottom surface of the thermal transfer component is coupled to the bottom surface of the first TEC, and wherein the thermal transfer component is tapered such that the bottom surface is smaller than the top surface; and
a second TEC comprising a top surface and a bottom surface, wherein the bottom surface of the second TEC is coupled to the top surface of the thermal transfer component, and wherein the second TEC is larger than the first TEC.
